(19) United States
(12) Patent Application Publication
(10) Pub. No.: US 2016/0172625 A1
(43) Pub. Date: Jun. 16, 2016

(54) BARRIER LAMINATE, GAS BARRIER FILM, AND DEVICE

(71) Applicant: FUJIFILM Corporation, Tokyo (JP)

(72) Inventors: Atsushi MUKAI, Ashigarakami-gun (JP); Makoto YAMADA, Ashigarakami-gun (JP); Yuya MOTOMURA, Ashigarakami-gun (JP)

(73) Assignee: FUJIFILM Corporation, Tokyo (JP)

(21) Appl. No.: 15/047,384

(22) Filed: Feb. 18, 2016

Related U.S. Application Data
(63) Continuation of application No. PCT/JP2014/072749, filed on Aug. 29, 2014.

(30) Foreign Application Priority Data
Aug. 30, 2013 (JP) 2013-179913

(51) Int. Cl. H01L 51/52; H01L 31/048

(52) U.S. Cl. CPC H01L 51/5256; H01L 31/0481

(57) ABSTRACT

Provided are a barrier laminate, a gas barrier film including the barrier laminate, and a device including the gas barrier film. The barrier laminate includes an inorganic layer and a first organic layer, in which the inorganic layer and the first organic layer are in direct contact with each other, the first organic layer is formed by curing a polymerizable composition containing a polymerizable compound, a polymerization initiator, and a silane coupling agent represented by the following Formula (1) (in Formula (1), R2 represents a halogen element or an alkyl group, R3 represents a hydrogen atom or an alkyl group, L represents a divalent linking group, and n represents an integer of 0 to 2), the first organic layer contains titanium oxide fine particles, and the inorganic layer is formed on a surface of the first organic layer using a chemical vapor deposition method. The barrier laminate has high barrier properties and transparency.

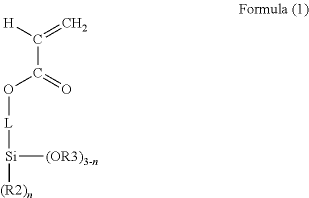

### CROSS-REFERENCE TO RELATED APPLICATIONS

This application is a continuation of PCT International Application No. PCT/JP2014/072749 filed on Aug. 29, 2014, which claims priority under 35 U.S.C §119 (a) to Japanese Patent Application No. 2013-179913 filed on Aug. 30, 2013, the entire content of which is incorporated herein by reference.

### BACKGROUND OF THE INVENTION

1. Field of the Invention

The present invention relates to a barrier laminate and a gas barrier film including the barrier laminate. In addition, the present invention relates to various devices including the barrier laminate or the gas barrier film.

2. Description of the Related Art

As a gas barrier film having a function of blocking water vapor, oxygen, and the like, a barrier film including a barrier laminate in which an organic layer and an inorganic layer are laminated on a plastic film as a substrate has been developed as a film having high barrier properties from various viewpoints.

For example, as a barrier film having high barrier properties, transparency, and high productivity, JP2011-73417A discloses a barrier film including an organic layer containing inorganic nanoparticles that is formed on an inorganic barrier layer formed of polysilazane. A technique is known that, when inorganic nanoparticles are added to an organic layer, the inorganic nanoparticles are surface-treated with a silane coupling agent (JP2013-77585A).

In addition, JP2011-201064A and JP2010-200780A disclose a technique of improving adhesion between an organic layer and an inorganic layer by adding a silane coupling agent and a polymerizable acidic compound to a polymerizable composition for forming the organic layer.

### SUMMARY OF THE INVENTION

An object of the present invention is to provide a barrier laminate and a gas barrier film which have high barrier properties and transparency.

The present inventors made an attempt to improve the transparency of a barrier laminate by adding inorganic nanoparticles to an organic layer as described in the methods described in JP2011-73417A and JP2013-77585A and found that there is a problem in that an inorganic layer and the organic layer are peeled off from each other. It is considered that the problem is caused due to the following reasons: the adhesion in an interface between the inorganic layer and the organic layer is insufficient; and the organic layer is likely to aggregate. Therefore, the present inventors performed further investigation on a silane coupling agent, which is added to a composition for forming an organic layer, and an inorganic layer which is formed on a surface of the organic layer, thereby completing the present invention.

That is, the present invention provides the following [ ]] to [15].

[1] A barrier laminate including:

an inorganic layer; and

a first organic layer,

in which the inorganic layer and the first organic layer are in direct contact with each other,

the first organic layer is formed by curing a polymerizable composition containing a polymerizable compound, a polymerization initiator, and a silane coupling agent represented by the following Formula (1):

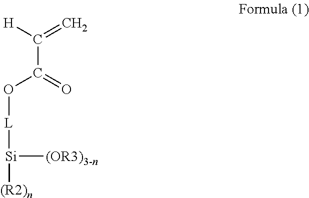

where R2 represents a halogen element or an alkyl group, R3 represents a hydrogen atom or an alkyl group, L represents a divalent linking group, and n represents an integer of 0 to 2,

the first organic layer contains titanium oxide fine particles, and

the inorganic layer is formed on a surface of the first organic layer using a chemical vapor deposition method.

[2] The barrier laminate according to [1],

wherein a ratio of the mass of the silane coupling agent to the total mass of the polymerizable compound, the polymerization initiator, and the silane coupling agent is 2.5 mass % or higher and lower than 50 mass %.

[3] The barrier laminate according to [1] or [2], further including:

a second organic layer,

in which the inorganic layer and the second organic layer are in direct contact with each other,

the second organic layer is formed by curing a polymerizable composition containing a polymerizable compound, a polymerization initiator, and the silane coupling agent represented by Formula (1), and

the second organic layer contains titanium oxide fine particles.

[4] The barrier laminate according to [3],

in which in the first organic layer, a ratio of the mass of the silane coupling agent to the total mass of the polymerizable compound, the polymerization initiator, and the silane coupling agent is 10 mass % to 30 mass %, and

in the second organic layer, a ratio of the mass of the silane coupling agent to the total mass of the polymerizable compound, the polymerization initiator, and the silane coupling agent is 5 mass % to 30 mass %.

[5] The barrier laminate according to [3] or [4],

in which the polymerizable composition used for forming the first organic layer is the same as the polymerizable composition used for forming the second organic layer.

[6] The barrier laminate according to any one of [1] to [5],

in which the inorganic layer is formed of silicon nitride or silicon oxynitride.

[7] The barrier laminate according to [6],

in which a thickness of the inorganic layer is 15 nm to 50 nm, and

a percentage oxygen content in a region within 5 nm from a surface of the inorganic layer opposite to the first organic layer side is higher than those of other regions of the inorganic layer.

[8] The barrier laminate according to any one of [1] to [7],

in which the polymerizable composition for forming the first organic layer does not contain a silane coupling agent having no polymerizable group.

[9] The barrier laminate according to any one of [1] to [8],

wherein a ratio of the volume of the titanium oxide fine particles to the volume of the organic layer is 15% to 50%.

[10] The barrier laminate according to any one of [1] to [9],

in which a structure is adopted in which at least two organic layers and at least two inorganic layers are alternately laminated.

[11] The barrier laminate according to any one of [1] to [10],

in which the polymerizable compound is an acrylic compound.

[12] The barrier laminate according to any one of [1] to [11],

in which the polymerizable compound is a polyfunctional acrylic compound having at least a bifunctional or higher polymerizable group.

[13] A gas barrier film including:

a substrate; and

the barrier laminate according to any one of [1] to [12].

[14] A device including:

a substrate that includes the barrier laminate according to any one of [1] to [12].

[15] A device which is sealed using the barrier laminate according to any one of [1] to [12].

According to the present invention, a barrier laminate and a gas barrier film which have high barrier properties and transparency are provided. When the barrier laminate and the gas barrier film according to the present invention are used for a device such as an organic electronic device, the light use efficiency does not deteriorate due to reflection, and high barrier properties can be obtained.

### BRIEF DESCRIPTION OF THE DRAWINGS

FIG. 1 is a schematic cross-sectional view showing an example of a barrier laminate (gas barrier film) according to the present invention.

FIG. 2 is a diagram showing a composition of a standard inorganic oxide film of Examples.

FIG. 3 is a graph showing the results of measuring a change in refractive index while changing the content of titanium oxide fine particles in an organic layer.

FIG. 4 is a graph showing an effect of the refractive index of the organic layer on the transparency of a barrier laminate.

FIG. 5 is atomic force microscope images showing surfaces of an organic layer containing titanium oxide fine particles and an organic layer containing no titanium oxide fine particles.

### DESCRIPTION OF THE PREFERRED EMBODIMENTS

Hereinafter, the details of the present invention will be described in detail. In this specification of the present application, numerical ranges represented by “to” include numerical values before and after “to” as lower limits and upper limits. In addition, “organic EL element” according to the present invention refers to an organic electroluminescence element. In this specification, “(meth)acrylate” represents “either or both of acrylate and methacrylate”. The same shall be applied to “(meth)acrylic acid”.

A barrier laminate according to the present invention includes: an inorganic layer; and an organic layer that is provided on a surface of the inorganic layer. The organic layer is formed by curing a polymerizable composition containing a polymerizable compound, a silane coupling agent represented by the following Formula (1), and a polymerization initiator. The organic layer contains titanium oxide fine particles.

(Barrier Laminate)

The barrier laminate contains at least one organic layer and at least one inorganic layer and may have a structure in which two or more organic layers and two or more inorganic layers are alternately laminated.

In the barrier laminate, within a range not departing from the scope of the present invention, a composition constituting the barrier laminate may contain a so-called gradient material layer in which an organic region and an inorganic region changes continuously in a thickness direction of the barrier laminate. Examples of the gradient material include a material described in “Journal of Vacuum Science and Technology A” (Kim et. al, Vol. 23, p 971-977, 2005 American Vacuum Society)” and a continuous layer described in US2004/46497 in which an interface is formed between an organic region and an inorganic region. Hereinafter, in order to simplify the description, the organic layer and the organic region will be referred to as “organic layer”, and the inorganic layer and the inorganic region will be referred to as “inorganic layer”.

In this specification, an organic layer on which an inorganic layer is provided will also be referred to as “first organic layer”, and an organic layer that is formed on a surface of the inorganic layer will also be referred to as “second organic layer”.

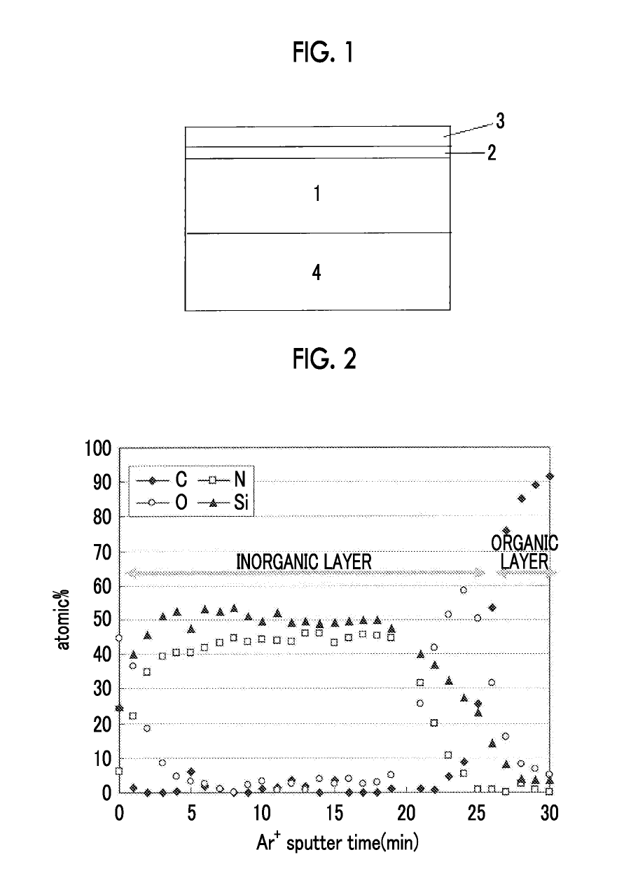

It is preferable that the barrier laminate according to the present invention includes a first organic layer and an inorganic layer that is provided on a surface of the first organic layer. It is also preferable that a second organic layer is provided on a surface of the inorganic layer. In addition, it is preferable that a gas barrier film has a configuration in which a first organic layer is provided on a substrate and in which an inorganic layer is provided on a surface of the first organic layer, and it is also preferable that a second organic layer is provided on a surface of the inorganic layer. FIG. 1 is a schematic cross-sectional view showing an example of a barrier laminate (gas barrier film) according to an embodiment of the present invention, in which Reference numeral 1 represents a first organic layer, reference numeral 2 represent an inorganic layer, reference numeral 3 represents a second organic layer, and reference numeral 4 represents a substrate.

The number of layers constituting the barrier laminate is not particularly limited and, typically, is preferably 2 to 30 and more preferably 3 to 20. In addition, the barrier laminate may include a constituent layer in addition to the organic layer and the inorganic layer.

(Silane Coupling Agent)

In the barrier laminate according to the present invention, a silane coupling agent represented by the following Formula (1) may be used.

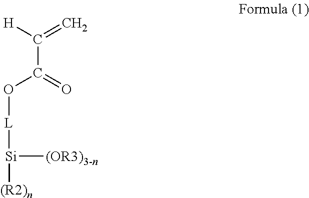

In Formula (1), R2 represents a halogen element or an alkyl group, R3 represents a hydrogen atom or an alkyl group, L represents a divalent linking group, and n represents an integer of 0 to 2.

Examples of the halogen element include a chlorine atom, a bromine atom, a fluorine atom, and an iodine atom.

The number of carbon atoms in the alkyl group or in an alkyl group of a substituent containing an alkyl group among substituents described below is preferably 1 to 12, more preferably 1 to 9, and still more preferably 1 to 6. Specific examples of the alkyl group include a methyl group, an ethyl group, a propyl group, a butyl group, a pentyl group, and a hexyl group. The alkyl group may be linear, branched, or cyclic but is preferably linear.

It is preferable that the divalent linking group is a linking group having 1 to 20 carbon atoms. The number of carbon atoms in the linking group is preferably 1 to 12 and more preferably 1 to 6. Examples of the divalent linking group include an alkylene group (for example, an ethylene group, a 1,2-propylene group, a 2,2-propylene group (also called a 2,2-propylidene group or a 1,1-dimethyl methylene group), a 1,3-propylene group, a 2,2-dimethyl-1,3-propylene group, a 2-butyl-2-ethyl-1,3-propylene group, a 1,6-hexylene group, 1,9-nonylene, a 1,12-dodecylene group, or a 1,16-hexadecylene group), an arylene group (for example, a phenylene group, or a naphthylene group), an ether group, an imino group, a carbonyl group, a sulfonyl group, and a divalent residue in which two or more of the above divalent groups are bonded to each other in series (for example, a polyethylene oxyethylene group, a polypropylene oxypropylene group, or a 2,2-propylenephenylene group). The above groups may have a substituent. In addition, a linking group obtained by bonding two or more of the groups bonded to each other in series may be used. Among these, an alkylene group, an arylene group, or a divalent group in which two or more of the groups are bonded to each other in series is preferable, and an unsubstituted alkylene group, an unsubstituted arylene group, or a divalent group in which two or more of the groups are bonded to each other in series is more preferable. Examples of the substituent include an alkyl group, an alkoxy group, an aryl group, and an aryloxy group.

The content of the silane coupling agent is preferably 1 mass % to 30 mass % and more preferably 5 mass % to 20 mass % with respect to the solid content of the polymerizable composition.

In addition, the barrier laminate according to the present invention may contain two or more kinds of silane coupling agents. In this case, the content of each of the silane coupling agents is within the above-described range.

Hereinafter, specific examples of the silane coupling agent will be shown, but the present invention is not limited thereto.

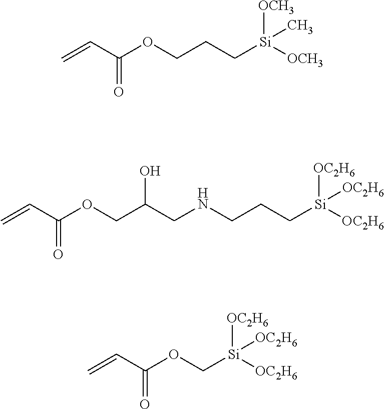

A ratio of the mass of the silane coupling agent to the total mass of the polymerizable compound, the polymerization initiator, and the silane coupling agent is preferably 2.5 mass % or higher and lower than 50 mass %, more preferably 5 mass % to 30 mass %, and still more preferably 10 mass % to 30 mass %. Within the above-described range, the effects of the present invention tend to be more effectively exhibited.

By containing the silane coupling agent, even after being incorporated into a device, the polymerizable composition for forming the organic layer can exhibit high water vapor barrier properties while securing high adhesion. It is preferable that the silane coupling agent contain a polymerizable group, and it is more preferable that the silane coupling agent contains a (meth)acrylate group. The silane coupling agent has a lower refractive index than a polymer layer having a refractive index of, generally, about 1.5 which is formed by polymerization of (meth)acrylate. Therefore, as the content of the silane coupling agent increases, the refractive index of the organic layer tends to decrease. It is considered that high adhesion is derived from a polymerizable group of a silane coupling agent. Therefore, it is preferable that the polymerizable composition for forming the organic layer does not substantially contain a silane coupling agent having no polymerizable group. It is more preferable that the polymerizable composition for forming the organic layer does not substantially contain a silane coupling agent other than the silane coupling agent represented by Formula (1). “Not substantially containing” represents that, for example, the content of the silane coupling agent is 0.1 mass % or lower with respect to all the components of the polymerizable composition.

(Organic Layer)

Preferably, the organic layer can be formed by curing a polymerizable composition containing a polymerizable compound, a silane coupling agent, and a polymerization initiator after adjusting the polymerizable composition to have a layered structure.

In a method of adjusting the polymerizable composition to have a layered structure, typically, the polymerizable composition is formed by application on a support such as a substrate or an inorganic layer. Examples of an application method include a dip coating method, an air knife coating method, a curtain coating method, a roller coating method, a wire bar coating method, a gravure coating method, a slide coating method, and an extrusion coating method using a hopper described in U.S. Pat. No. 2,681,294B. Among these, an extrusion coating method can be preferably adopted.

(Polymerizable Compound)

The polymerizable compound used in the present invention is a compound having an ethylenically unsaturated bond in a terminal or a side chain thereof and/or a compound having epoxy or oxetane in a terminal or a side chain thereof. Among these, a compound having an ethylenically unsaturated bond in a terminal or a side chain thereof is preferable. Examples of the compound having an ethylenically unsaturated bond in a terminal or a side chain thereof include a (meth)acrylic compound, an acrylamide-based compound, a styrene-based compound, and maleic anhydride. Among these, a (meth)acrylic compound is preferable, and an acrylic compound is more preferable.

As the (meth)acrylic compound, for example, (meth)acrylate, urethane (meth)acrylate, polyester (meth)acrylate, or epoxy(meth)acrylate is preferable.

As the styrene-based compound, for example, styrene, α-methyl styrene, 4-methyl styrene, divinylbenzene, 4-hydroxy styrene, or 4-carboxy styrene is preferable.

Hereinafter, specific examples of the (meth)acrylic compound will be shown, but the present invention is not limited thereto.

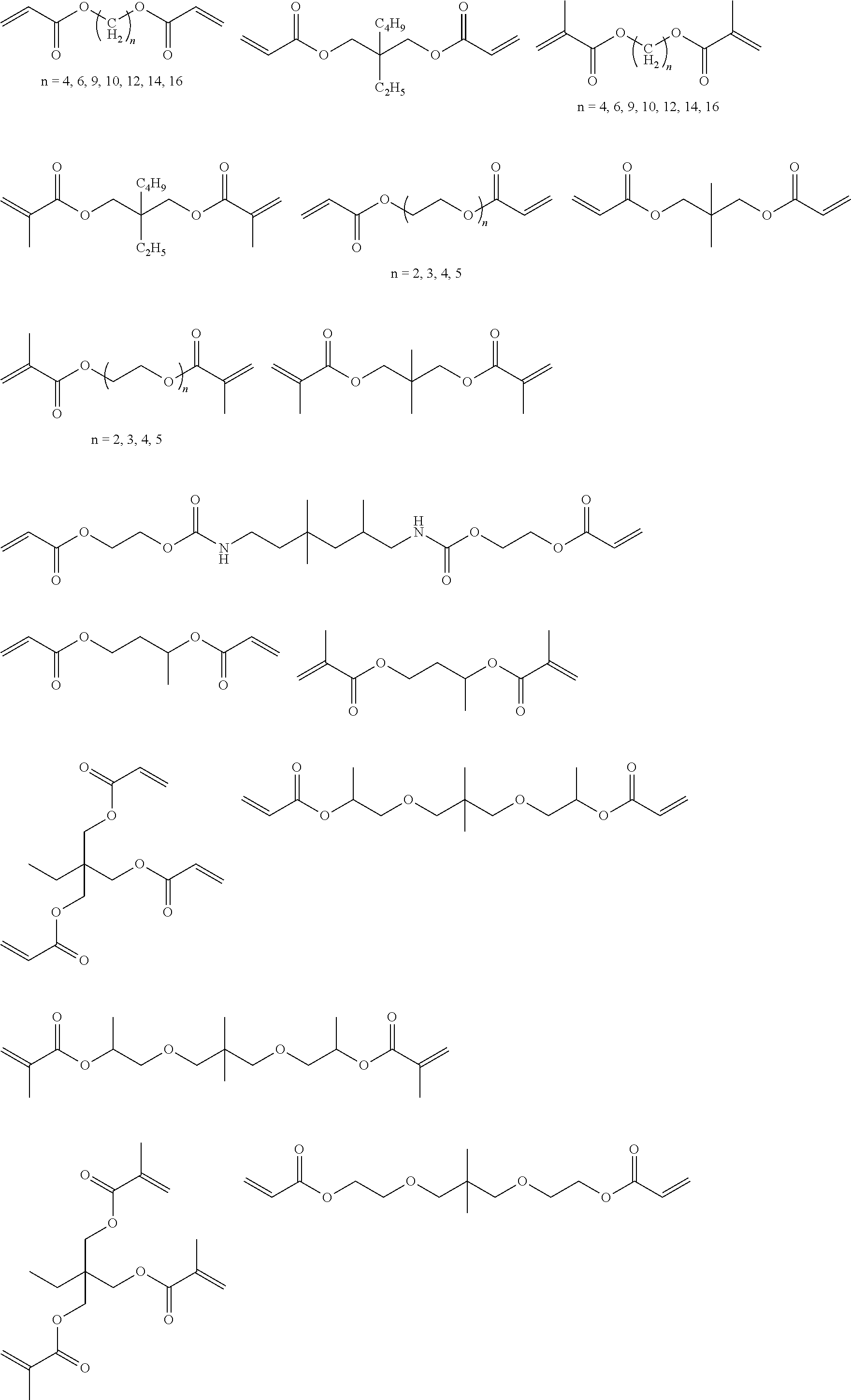

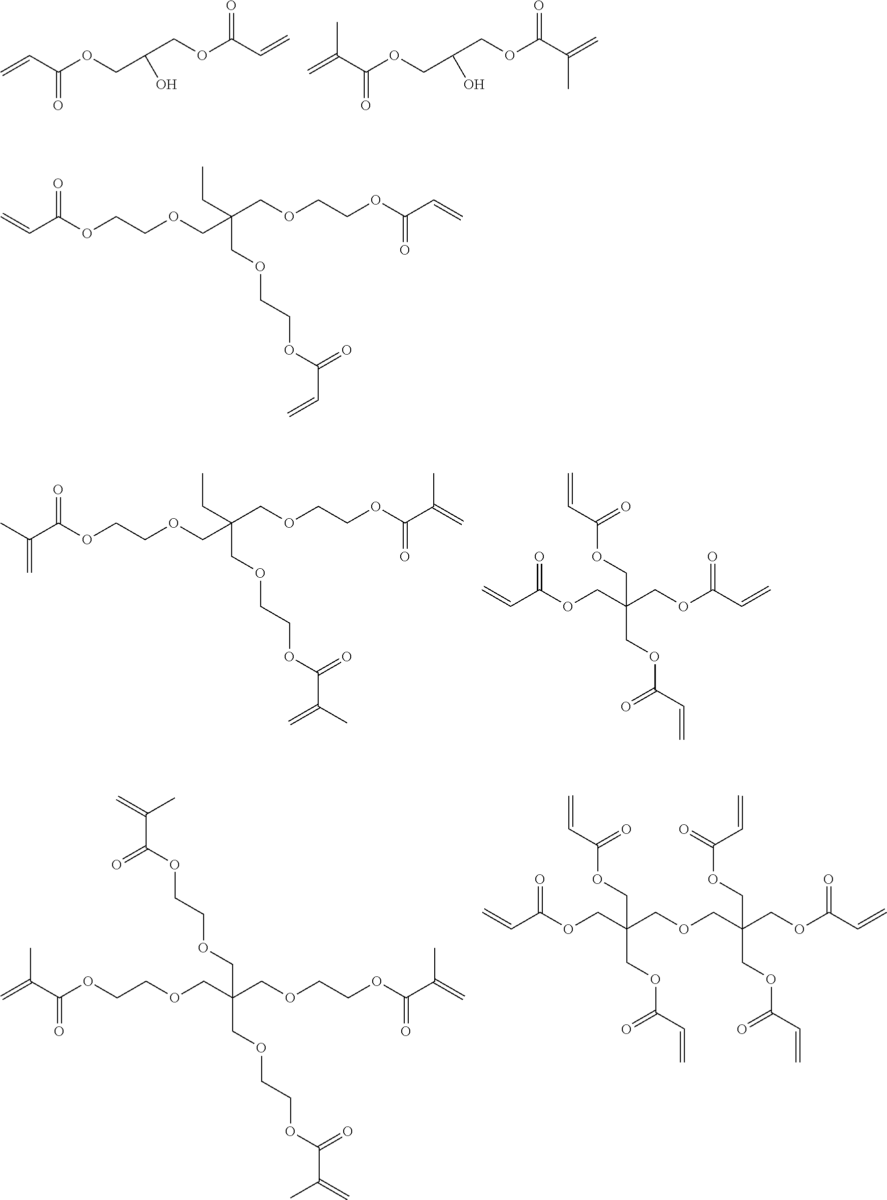

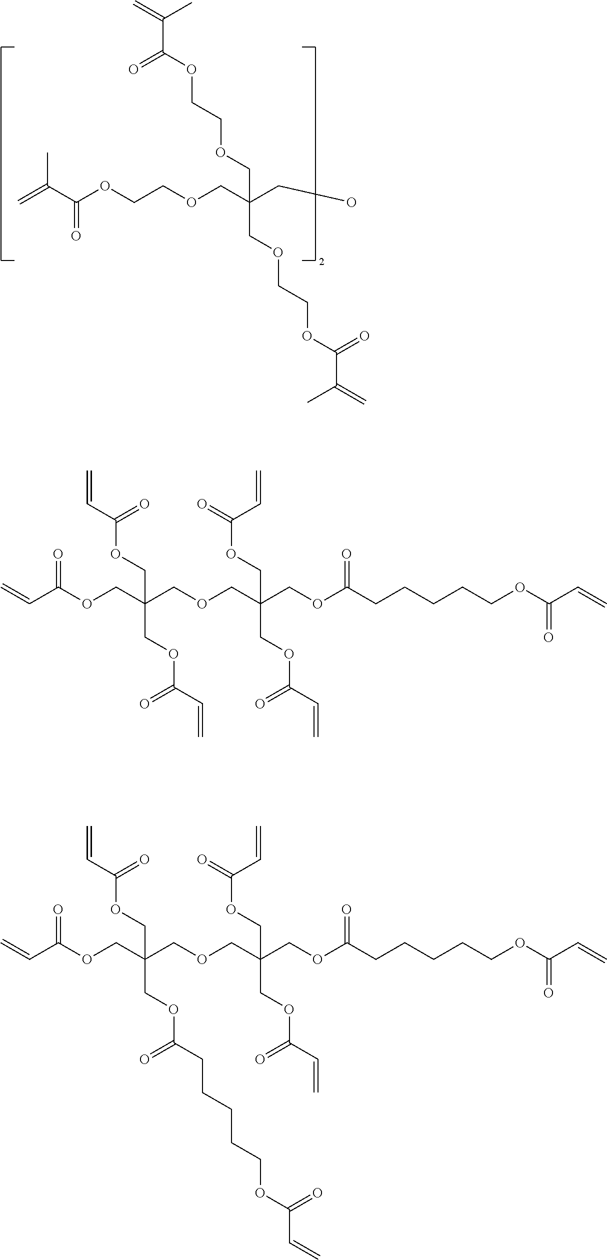

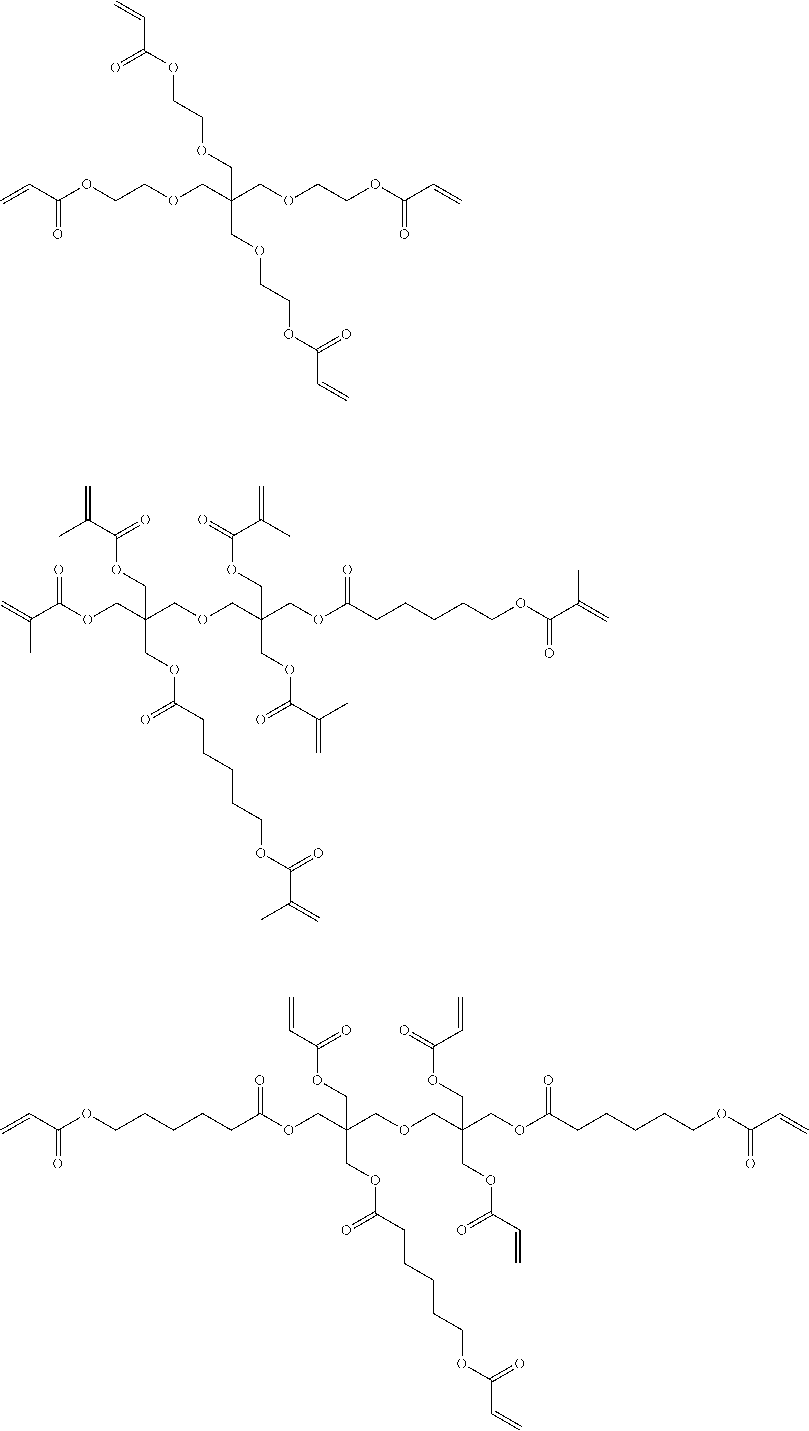

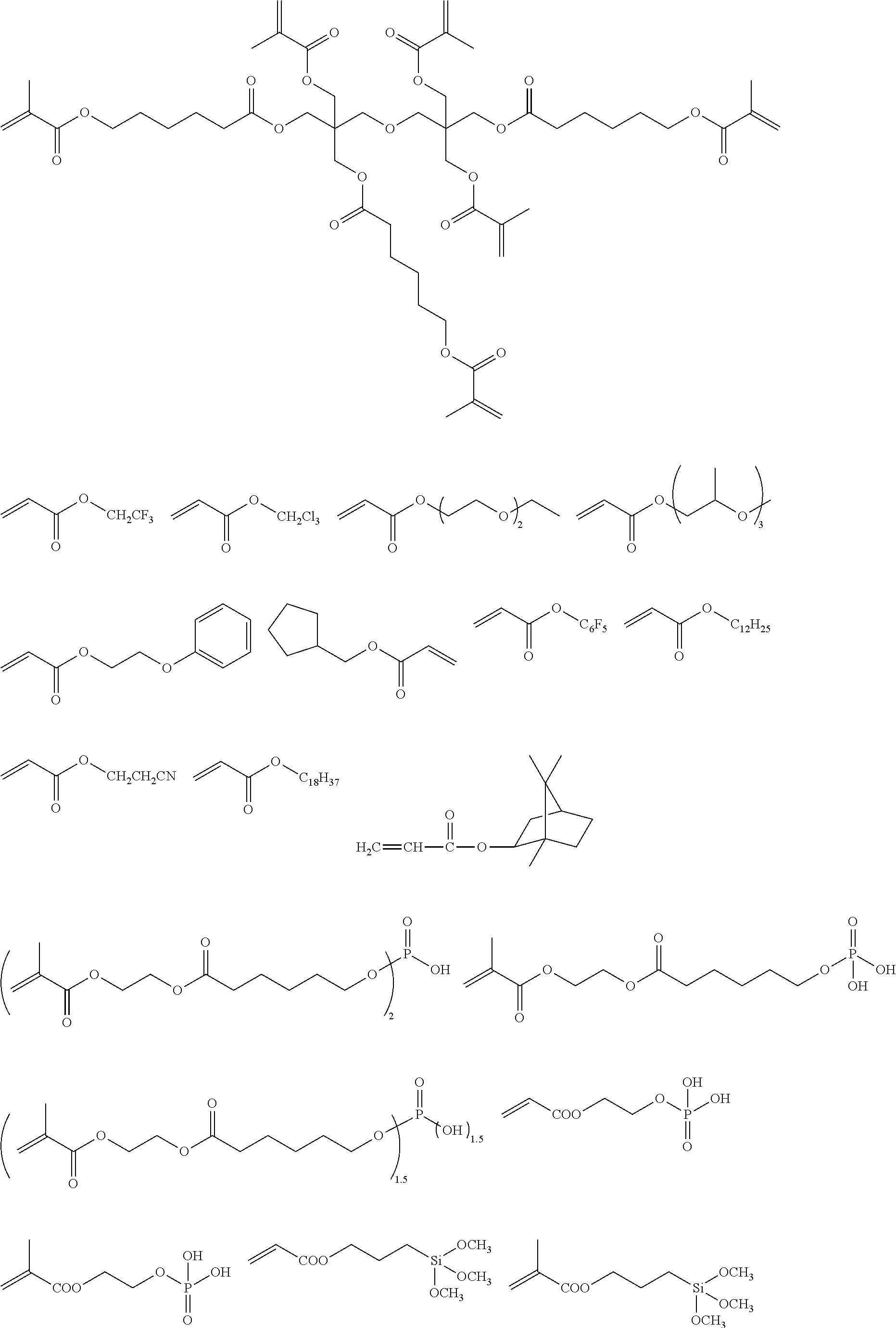

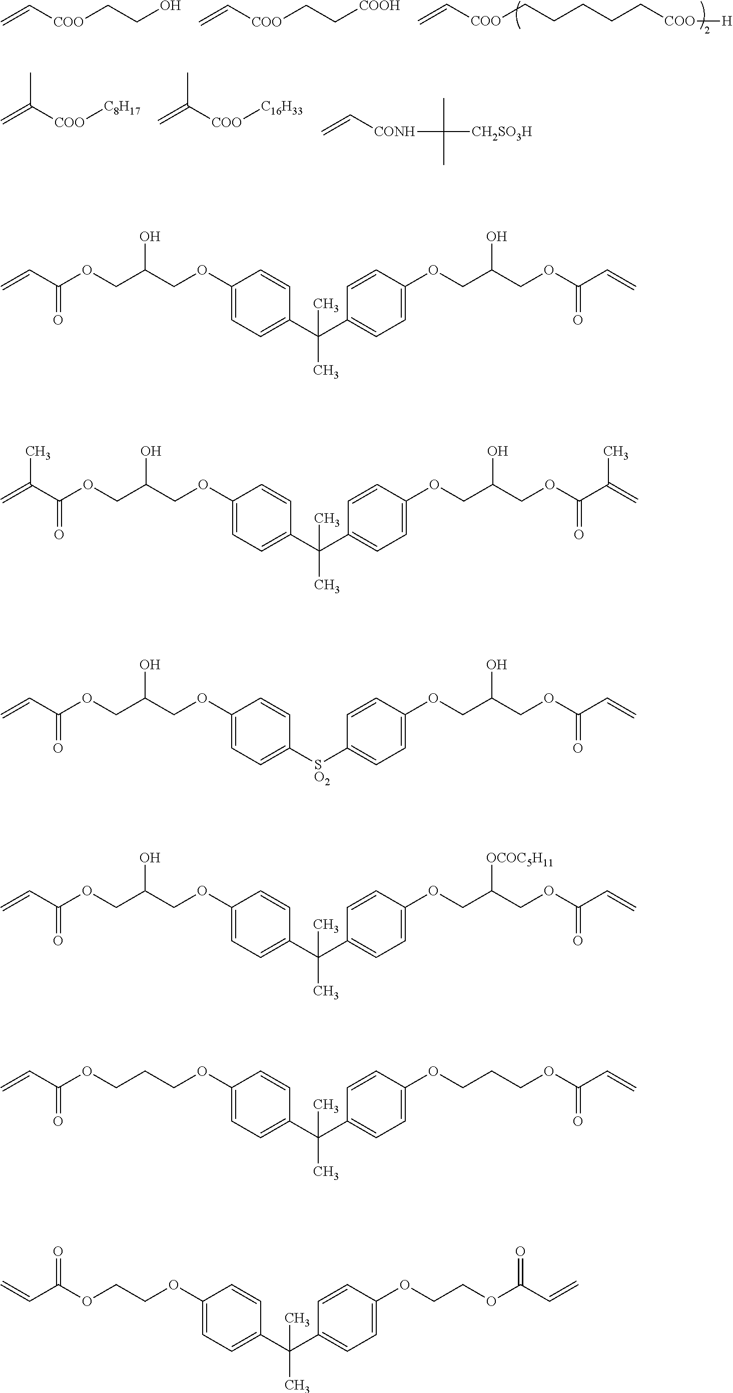

Further, in the present invention, a methacrylic compound represented by the following Formula (2) can be preferably adopted.

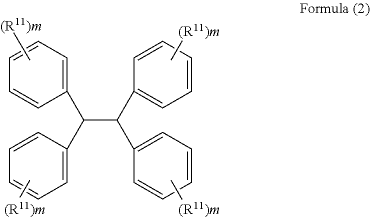

(In Formula (2), R¹¹'s each independently represents a substituent and may be the same as or different from each other; m's each independently represents an integer of 0 to 5 and may be the same as or different from each other; and at least one of R¹¹'s contains a polymerizable group.)

It is preferable that R¹¹ represents groups obtained from a combination of a polymerizable group with at least one of —CR²²— (R²² represents a hydrogen atom or a substituent), —CO—, —O—, a phenylene group, —S—, —C≡C—, —NR²³— (R²³ represents a hydrogen atom or a substituent), and —CR²⁴═CR²⁵— (R²⁴ and R²⁵ each independently represents a hydrogen atom or a substituent). Among these, a group obtained from a combination of a polymerizable group with at least one of —CR²²— (R²² represents a hydrogen atom or a substituent)-CO—, —O—, and a phenylene group is preferable. R²² represents a substituent or a substituent. It is preferable that R²² represents a substituent or a hydroxy group.

It is preferable that at least one of R¹¹'s contains a hydroxy group. By containing a hydroxy group, the curing rate of the organic layer is improved. The molecular weight of at least one of R¹¹'s is preferably 10 to 250 and more preferably 70 to 150. It is preferable that binding positions of R¹¹'s include at least a para position.

m's each independently represents an integer of 0 to 5, preferably an integer of 0 to 2, more preferably 0 or 1, and still more preferably 1.

It is preferable that the compound represented by Formula (2) has a structure in which at least two of R¹¹'s have the same structure. Further, it is more preferable that all of four m's represent 1 and that at least each pair of R¹¹'s among four R¹¹'s have the same structure. It is still more preferable that all of m's represent 1 and that all of R¹¹'s have the same structure. As the polymerizable group contained in the compound represented by Formula (2), a (meth)acryloyl group or an epoxy group is preferable, and a (meth)acryloyl group is more preferable. The number of polymerizable groups contained in the compound represented by Formula (2) is preferably 2 or more and more preferably 3 or more. In addition, the upper limit of the number of polymerizable groups is not particularly limited but is preferably 8 or less and more preferably 6 or less.

The molecular weight of the compound represented by Formula (2) is preferably 600 to 1400 and more preferably 800 to 1200.

In the present invention, only one kind or two or more kinds may be contained as the compound represented by Formula (2). When two or more kinds are contained, for example, the composition may contain compounds, which contain R¹¹'s having the same structure but are different from each other in the number of R¹¹'s, and isomers thereof.

Hereinafter, specific examples of the compound represented by Formula (2) will be shown, but the present invention is not limited thereto. In addition, in the following compounds, all of four m's in Formula (2) represent 1. However, compounds in which one, two, or three of four m's in Formula (2) represent 0 (for example, bifunctional or trifunctional compounds) compounds in which one, two, or three or more of four m's in Formula (2) represent 2 or more (for example, pentafunctional or tetrafunctional compounds in which two or more R¹¹'s are bonded to one ring) are also included as preferable compound examples of the present invention.

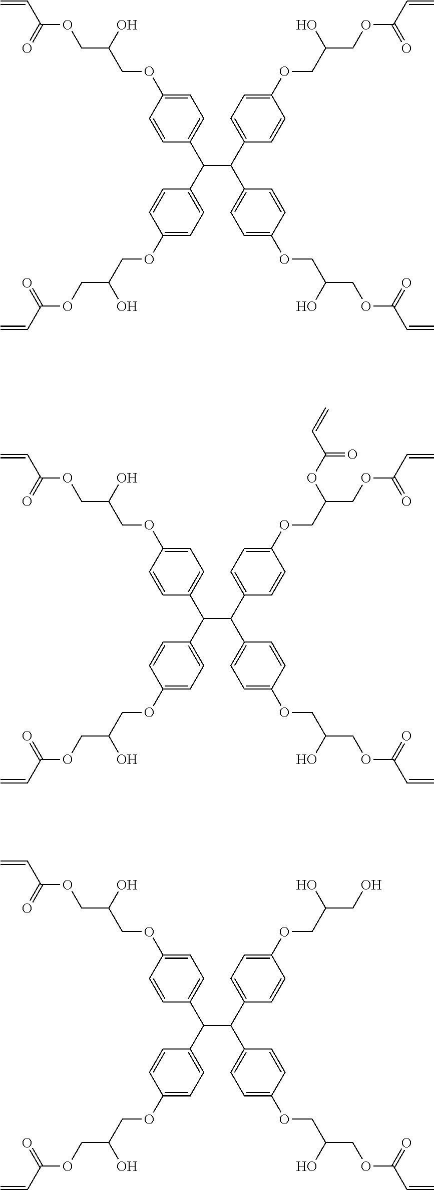

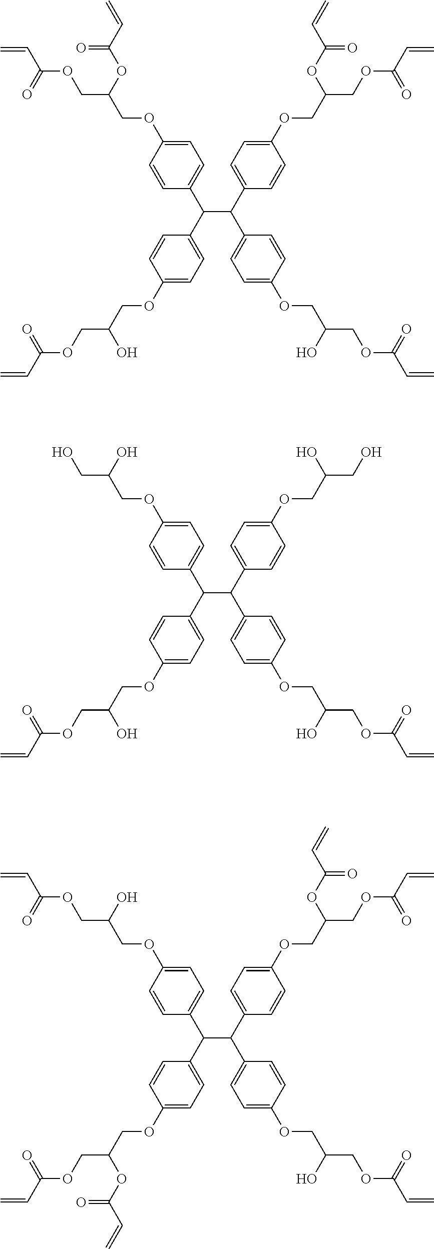

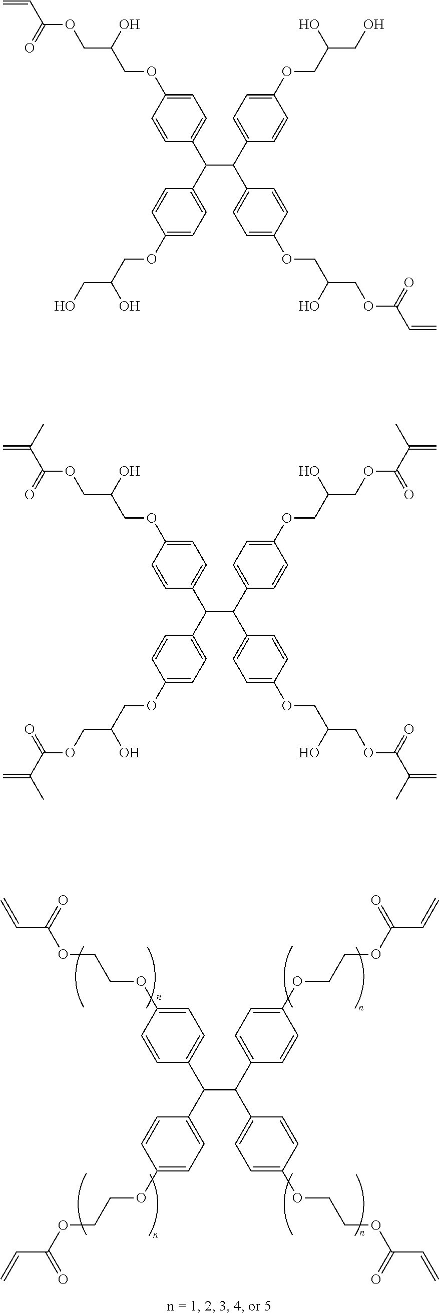

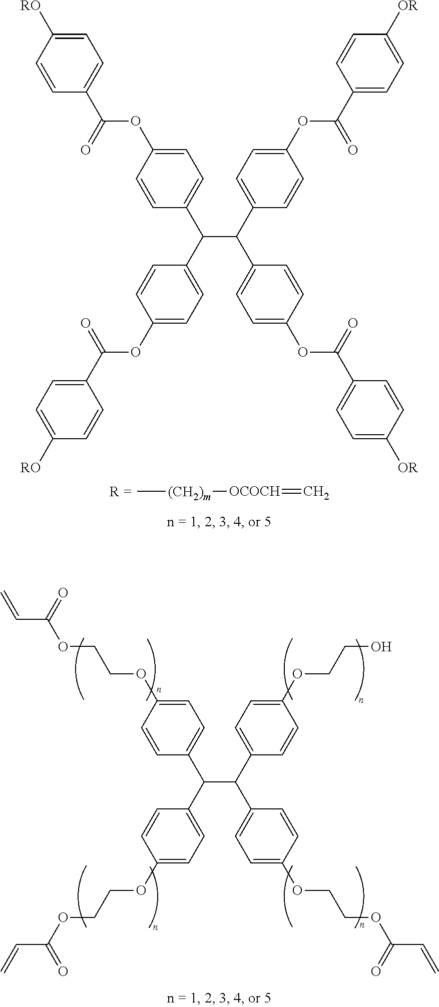

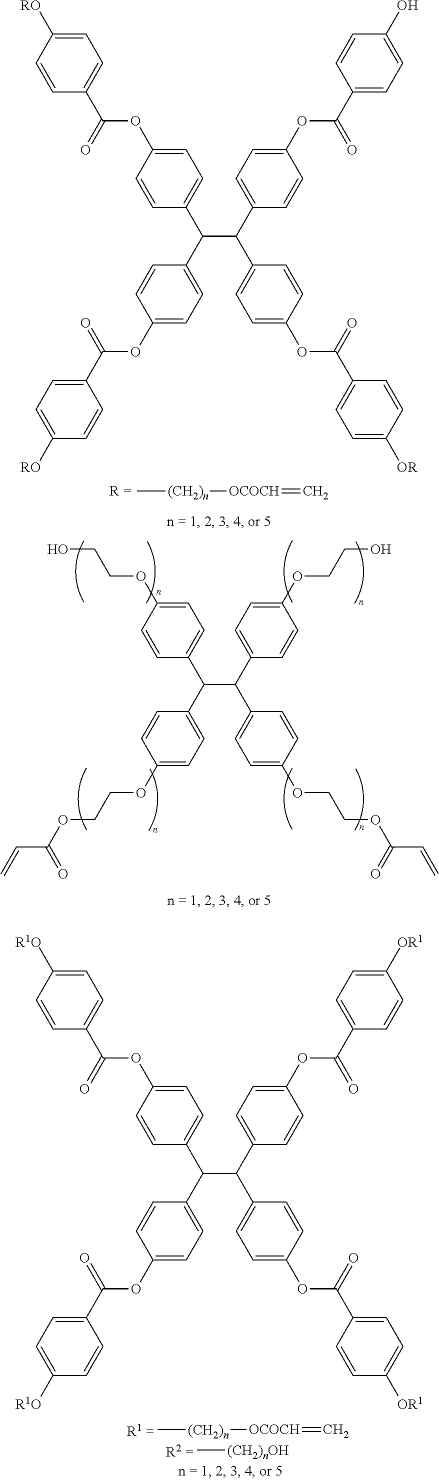

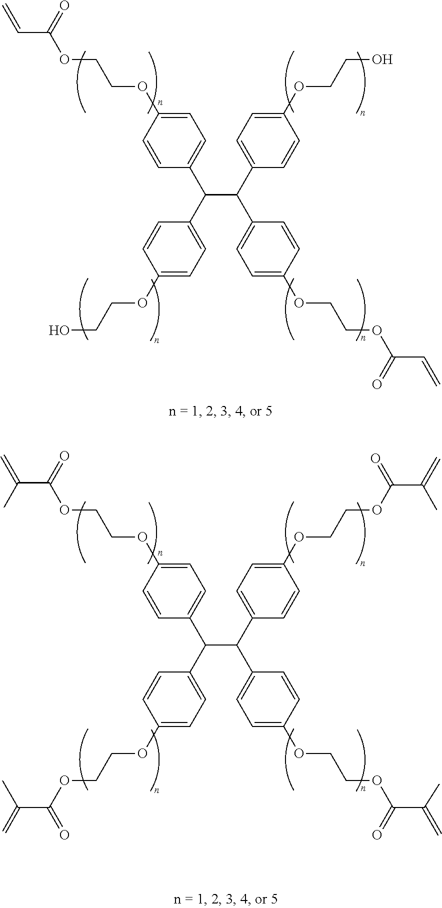

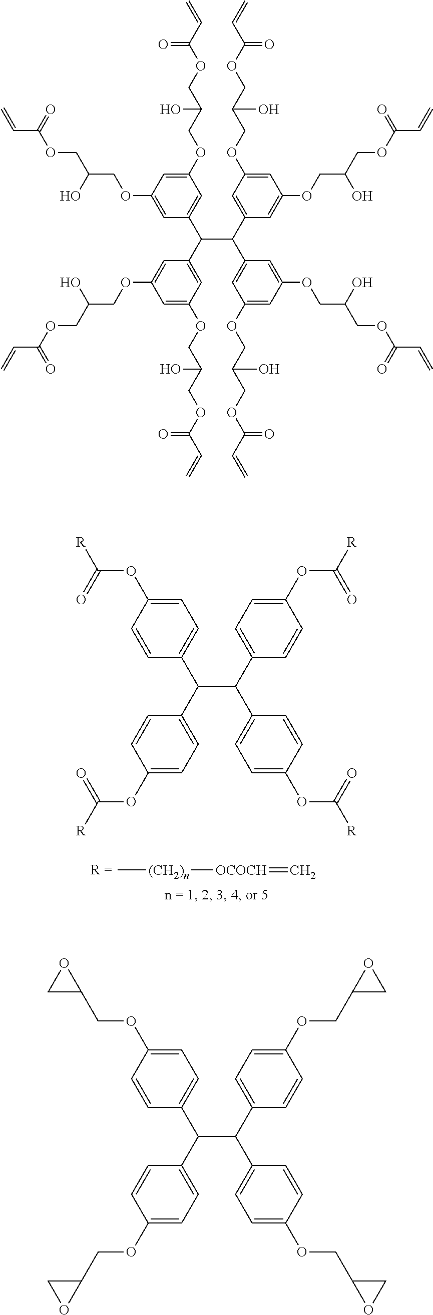

The compound represented by Formula (2) can be obtained from a commercially available product. In addition, the compound can also be synthesized using a well-known method. For example, epoxy acrylate can be obtained from a reaction between an epoxy compound and acrylic acid. Typically, these compound produces bifunctional, trifunctional, and pentafunctional compounds and isomers thereof during the reaction. These isomers can be isolated by column chromatography and, in the present invention, can be used as a mixture.

(Polymerization Initiator)

Typically, the polymerizable composition according to the present invention contains a polymerization initiator. When the polymerization initiator is used, the content thereof is preferably 0.1 mol % or higher and more preferably 0.5 mol % to 2 mol % with respect to the total amount of the compound contributing to the weight. With this composition, a polymerization reaction during which an active component-producing reaction occurs can be appropriately controlled. Examples of a photopolymerization initiator include IRGACURE series manufactured by Ciba Specialty Chemicals K.K. (for example, IRGACURE 651, IRGACURE 754, IRGACURE 184, IRGACURE 2959, IRGACURE 907, IRGACURE 369, IRGACURE 379, and IRGACURE 819), DAROCURE series (for example, DAROCURE TPO and DAROCURE 1173), QUANTACURE PDO, and EZACURE series manufactured by Lamberti S.p.A. (for example, EZACURE TZM, EZACURE TZT, and EZACURE KT046).

The polymerizable composition containing a silane coupling agent, a polymerizable compound, and a polymerization initiator may be cured by light (for example, ultraviolet rays), electron beams, or heat rays. However, it is preferable that the polymerizable composition is cured by light. In particular, it is preferable that the polymerizable composition is cured after being heated at a temperature of 25° C. or higher (for example, 30° C. to 130° C.). With the above-described configuration, the hydrolysis reaction of the silane coupling agent is promoted, the polymerizable composition is effectively cured, and the layers can be formed without damaging the substrate and the like.

The polymerization ratio of the polymerizable compound in the polymerizable composition is preferably 60 mass % or higher, more preferably 70 mass % or higher, still more preferably 80 mass % or higher, and even still more preferably 90 mass %. When the inorganic layer is formed on the surface of the organic layer, the organic layer may be damaged. For example, the surface of the organic layer may be etched to be roughened by plasma used in a CVD method, which may decrease barrier properties. When the polymerization ratio of the polymerizable compound can be increased, such a damage is likely to be suppressed. When an acrylic compound is used as the polymerizable compound, the polymerization ratio tends to increase, which is preferable.

Typically, the irradiation light is ultraviolet rays emitted from a high-pressure mercury lamp or a low-pressure mercury lamp. The irradiation energy is preferably 0.1 J/cm² or higher and more preferably 0.5 J/cm² or higher. When a (meth)acrylic compound is used as the polymerizable compound, polymerization is inhibited by oxygen in the air. Therefore, it is preferable that the oxygen concentration or oxygen partial pressure during the polymerization decreases. When the oxygen concentration during the polymerization is decreased using a nitrogen substitution method, the oxygen concentration is preferably 2% or lower and more preferably 0.5% or lower. When the oxygen partial pressure during the polymerization is decreased using an evacuation method, the total pressure is preferably 1000 Pa or lower and more preferably 100 Pa or lower. In addition, it is preferable that ultraviolet polymerization is performed by irradiation at an energy of 0.5 J/cm² under reduced pressure conditions of 100 Pa or lower.

It is preferable that the organic layer is smooth and has high hardness. Regarding the smoothness of the organic layer, the average roughness (Ra value) of a 1 μm×1 μm region is preferably less than 1 nm and more preferably less than 0.5 nm. The polymerization ratio of the monomer is preferably 85% or higher, more preferably 88% or higher, still more preferably 90% or higher, and even still more preferably 92% or higher. The polymerization ratio described herein refers to a ratio of reacted polymerizable groups to all the polymerizable groups (for example, an acryloyl group and a methacryloyl group) in a monomer mixture. The polymerization ratio can be determined by an infrared absorption method.

The thickness of the organic layer is not particularly limited. However, when the thickness is excessively small, it is difficult to obtain the uniformity of the thickness, and when the thickness is excessively large, cracking may occur due to an external force, which decreases barrier properties. From this point of view, the thickness of the organic layer is preferably 50 nm to 3000 nm and more preferably 200 nm to 2000 nm.

It is required that foreign matter such as particles and protrusions are not present on the surface of the organic layer. Therefore, it is preferable that the organic layer is formed in a clean room. The cleanliness is preferably class 10000 or lower and more preferably class 1000 or lower.

It is preferable that the hardness of the organic layer is high. it is known that, when the hardness of the organic layer is high, the inorganic layer is formed to be smooth, which improves barrier performance. The hardness of the organic layer can be represented as a microhardness based on a nano-indentation method. The microhardness of the organic layer is preferably 100 N/mn or higher and more preferably 150 N/nm or higher.

[Titanium Oxide Fine Particle]

In the barrier laminate according to the present invention, the organic layer contains titanium oxide fine particles.

When a difference in refractive index between the organic layer and a layer adjacent thereto, the reflectance of the barrier laminate increases, and the light transmittance decreases. The refractive index of a polymer layer which is formed by polymerization of (meth)acrylate is n=1.6 at the highest. On the other hand, the inorganic layer formed of silicon nitride or silicon oxynitride has high density and can realize high barrier performance but has a high refractive index of about 1.9. (the refractive index of the air is 1.0, and the average refractive index of the substrate is 1.6). By the organic layer containing titanium oxide fine particles, the refractive index of the organic layer increases. As a result, a decrease in transmittance caused by reflection due to a difference in refractive index between the organic layer and the inorganic layer or color unevenness caused by multiple interference can be reduced.

The refractive index of the organic layer is preferably 1.6 to 2.0 and more preferably 1.7 to 1.9.

It is more preferable that the organic layer contains titanium oxide fine particles which are treated to be photocatalytically inactive. The photocatalytically inactive titanium oxide fine particles are not particularly limited as long as they do not have photocatalytic activity and can be appropriately selected according to the purpose. Examples of the photocatalytically inactive titanium oxide fine particles include: (1) titanium oxide fine particles having surfaces coated with at least one of alumina, silica, and zirconia; and (2) titanium oxide fine particles obtained by further coating the coated surfaces of the titanium oxide fine particle of (1) with a resin. Examples of the resin include poly(methyl methacrylate) (PMMA).

For example, using a methylene blue method it can be verified that the photocatalytically inactive titanium oxide fine particles do not have photocatalytic activity.

Titanium oxide fine particles before being treated to be photocatalytically inactive are not particularly limited and can be appropriately selected according to the purpose. As a major component of a crystal structure of the titanium oxide fine particles, a rutile structure, a mixed crystal structure of rutile and anatase, or an anatase structure is preferable, and a rutile structure is more preferable.

The titanium oxide fine particles may be particles of a composite obtained by adding a metal oxide in addition to titanium oxide.

As the metal oxide which can be used to form composite titanium oxide fine particles, at least one metal oxide selected from Sn, Zr, Si, Zn, and Al is preferable.

The addition amount of the metal oxide to titanium is preferably 1 mol % to 40 mol %, more preferably 2 mol % to 35 mol %, and still more preferably 3 mol % to 30 mol %.

The average primary particle size of the titanium oxide fine particles is preferably 1 nm to 30 nm, more preferably 1 nm to 25 nm, and still more preferably 1 nm to 20 nm. By controlling the average primary particle size to be 30 nm or less, the cloudiness or precipitation in a dispersion can be prevented. In addition, by controlling the average primary particle size to be 1 nm or more, the titanium oxide fine particles can maintain the crystal structure without being amorphous and can be prevented from being gelated over time.

The average primary particle size can be measured, for example, by calculation based on a full width at half maximum of a diffraction pattern measured using an X-ray diffractometer or statistical calculation based on a diameter of a transmission electron microscope (TEM) image.

The shape of the titanium oxide fine particles is not particularly limited and can be selected according to the purpose. Preferable examples of the shape of the titanium oxide fine particles include a rice grain shape, a spherical shape, a cubic shape, a spindle shape, or an amorphous shape. As the titanium oxide fine particles, one kind may be used alone, two or more kinds may be used in combination.

In the photocatalytically inactive titanium oxide fine particles, the refractive index is preferably 2.2 to 3.0, more preferably 2.2 to 2.8, and still more preferably 2.2 to 2.6. It is preferable the refractive index is 2.2 or higher because the refractive index of the organic layer can be efficiently increased. It is preferable that the refractive index is 3.0 or less because defects such as discoloration do not occur in the photocatalytically inactive titanium oxide fine particles.

Here, it is difficult to measure the refractive index of fine particles such as titanium oxide fine particles having a high refractive index (1.8 or higher) and an average primary particle size of about 1 nm to 100 nm. However, the refractive index of fine particles can be measured as follows. A resin material whose refractive index is known is doped with titanium oxide fine particles such that the titanium oxide fine particles are dispersed in the resin material. Using this resin material, a coating film is formed on a Si substrate or a quartz substrate. The refractive index of the coating film is measured using an ellipsometer. The refractive index of the titanium oxide fine particles is determined based on the volume ratio of the titanium oxide fine particles to the resin material in the coating film.

The content of the photocatalytically inactive titanium oxide fine particles (content thereof including a coating film and a metal oxide for forming a composite) is preferably 15 vol % to 50 vol %, more preferably 20 vol % to 40 vol %, and still more preferably 25 vol % to 35 vol % with respect to the volume of the polymerizable composition for forming the organic layer (after the formation; excluding the volume of a solvent). When the content of the photocatalytically inactive titanium oxide fine particles is 50 vol % or higher, the occupancy of the titanium oxide fine particles in the organic layer increases, and adhesion with the inorganic layer decreases, which is not preferable. When the content of the photocatalytically inactive titanium oxide fine particles is 15 vol % or lower, the effect of improving the refractive index may not be sufficiently obtained.

(Inorganic Layer)

Typically, the inorganic layer is a thin layer formed of a metal compound. A method of forming the inorganic layer may be a chemical vapor deposition method (CVD). The CVD method has high coverage capability to the substrate having convex and concave portions. In particular, a plasma CVD method is preferable. Components contained in the inorganic layer are not particularly limited as long as they satisfy the above-described performance, and examples thereof include a metal oxide, a metal nitride, a metal carbide, a metal oxynitride, and a metal oxycarbide. For example, an oxide, a nitride, a carbide, an oxynitride, or an oxycarbide containing at least one selected from Si, Al, In, Sn, Zn, Ti, Cu, Ce, and Ta can be preferably used. Among these, an oxide, a nitride, or an oxynitride selected from Si, Al, In, Sn, Zn, and Ti is preferable, an oxide, a nitride, or an oxynitride of Si or Al is more preferable, and silicon nitride or silicon oxynitride is still more preferable. These components may contain another element as an auxiliary component.

For example, by an oxide, a nitride, or an oxynitride of a metal containing hydrogen, the inorganic layer may contain hydrogen. In this case, it is preferable that the hydrogen concentration in Rutherford forward scattering is 30% or lower.

Regarding the smoothness of the inorganic layer which is formed according to the present invention, the average roughness (Ra value) of a 1 μm×1 μm region is preferably less than 1 nm and more preferably 0.5 nm or less. Therefore, it is preferable that the inorganic layer is formed in a clean room. The cleanliness is preferably class 10000 or lower and more preferably class 1000 or lower.

The thickness of the inorganic layer is not particularly limited. Typically, the thickness of the single inorganic layer is 5 nm to 500 nm, preferably 10 nm to 200 nm, and more preferably 15 nm to 50 nm. The inorganic layer may have a laminate structure including plural sub-layers. In this case, the respective compositions of the sub-layers may be the same as or different from each other.

After the formation, the inorganic layer may be exposed to the air to increase the oxygen content on the outermost surface. As a result, binding between the inorganic layer and the silane coupling agent contained in the second organic layer which is subsequently provided is superior, stability is likely to be obtained. The outermost surface refers to a region within 10 nm, preferably, 5 nm from a surface (a surface of the inorganic layer opposite to the first organic layer side, an interface between the inorganic layer and the air, or, after the formation of the second organic layer, an interface between the inorganic layer and the second organic layer). Specifically, for example, when the thickness of the inorganic layer is 15 nm to 50 nm, it is preferable that the percentage oxygen content in a region within 5 nm from a surface of the inorganic layer opposite to the first organic layer side is higher than those of other regions of the inorganic layer.

(Lamination of Organic Layer and Inorganic Layer)

The organic layer and the inorganic layer can be laminated by sequentially repeating the manufacturing of the organic layer and the inorganic layer according to the desired layer configuration.

In particular, in the present invention, it is preferable that the inorganic layer is formed on the surface of the first organic layer.

(Functional Layer)

The barrier laminate according to the present invention may have a functional layer. The details of the functional layer will be specifically described paragraphs “0036” to “0038” of JP2006-289627A. Examples of other functional layers include a matting agent layer, a protective layer, a solvent resistant layer, an antistatic layer, a smoothing layer, an adhesion improving layer, a light shielding layer, an anti-reflection layer, a hard coating layer, a stress relaxation layer, an anti-fog layer, an antifouling layer, a printing object layer, and an easily adhesive layer.

(Use of Barrier Laminate)

Typically, the barrier laminate according to the present invention is provided on a support. By selecting this support, the barrier laminate according to the present invention can be used for various applications. The support includes not only a substrate but also various devices, optical members, and the like. Specifically, the barrier laminate according to the present invention can be used as a barrier layer of a gas barrier film. In addition, the barrier laminate and the gas barrier film according to the present invention can be used to seal a device in which barrier properties are required. The barrier laminate and the gas barrier film according to the present invention can also be applied to optical members. Hereinafter, the details will be described.

<Gas Barrier Film>

The gas barrier film includes a substrate and the barrier laminate that is formed on the substrate. In the gas barrier film, the barrier laminate according to the present invention may be provided only a single surface of the substrate or may be provided on both surfaces thereof. In the barrier laminate according to the present invention, it is preferable that the first organic layer, the inorganic layer, and the second organic layer are laminated in this order on the substrate. The outermost layer of the barrier laminate according to the present invention may be an inorganic layer or an organic layer.

The gas barrier film can be used as a film substrate which includes a barrier layer having a function of blocking oxygen, water, a nitrogen oxide, a sulfur oxide, ozone, and the like in the air.

The gas barrier film may include constituent elements (for example, a functional layer such as an easily adhesive layer) in addition to the barrier laminate and the substrate. The functional layer may be provided on the barrier laminate, between the barrier laminate and the substrate, or on a surface (back surface) of the substrate where the barrier laminate is not provided.

(Plastic Film)

In the gas barrier film according to the present invention, typically, a plastic film is used as the substrate. The material, thickness, and the like of the plastic film to be used is not particularly limited as long as the barrier laminate including the organic layer, the inorganic layer, and the like can be held. For example, the plastic film can be appropriately selected according to the intended use. Specific examples of the plastic film include thermoplastic resins such as a polyester resin, a methacrylic resin, a methacrylic acid-maleic acid copolymer, a polystyrene resin, a transparent fluorine resin, a polyimide, fluorinated polyimide resin, a polyimide resin, a polyamideimide resin, a polyetherimide resin, a cellulose acylate resin, a polyurethane resin, a polyether ether ketone resin, a polycarbonate resin, an alicyclic polyolefin resin, a polyarylate resin, a polyether sulfone resin, a polysulfone resin, a cycloolefin copolymer, a fluorene ring-modified polycarbonate resin, an alicyclic-modified polycarbonate resin, a fluorene ring-modified polyester resin, and an acryloyl compound.

When the gas barrier film according to the present invention is used as a substrate of a device such as an organic EL element described below, it is preferable that the plastic film is formed of a heat-resistant material. Specifically, it is preferable that the plastic film is formed of a highly heat-resistant and transparent material having a glass-transition temperature (Tg) of 100° C. or higher and/or a linear thermal expansion coefficient of 40 ppm/° C. or lower. Tg and the linear thermal expansion coefficient can be adjusted by, for example, an additive. Examples of the thermoplastic resin include polyethylene naphthalate (PEN: 120° C.), polycarbonate (PC: 140° C.), alicyclic polyolefin (for example, ZEONOR 1600, manufactured by Zeon Corporation; 160° C.), polyarylate (PAr: 210° C.), polyether sulfone (PES: 220° C.), polysulfone (PSF: 190° C.), a cycloolefin copolymer (COC: a compound described in JP2001-150584A:162° C.), polyimide (for example, NEOPULIM, manufactured by Mitsubishi Gas Chemical Co., Inc.: 260° C.), fluorene ring-modified polycarbonate (BCF-PC: a compound described in JP2000-227603A: 225° C.), alicyclic-modified polycarbonate (IP-PC: a compound described in JP2000-227603A: 205° C.), and an acryloyl compound (a compound described in JP2002-80616A: 300° C. or higher) (the temperatures in the parentheses represent Tg). In particular, when transparency is required, it is preferable that, for example, alicyclic polyolefin is used.

When the gas barrier film according to the present invention is used in combination with a polarizing plate, it is preferable that the barrier laminate of the gas barrier film is arranged on the innermost side (adjacent to a device) so as to face the inside of a cell. At this time, since the gas barrier film is arranged to be closer to the inside of the cells than the polarizing plate, the retardation value of the gas barrier film is important. It is preferable that the gas barrier film having the above-described configuration is used in the following forms: a form in which a gas barrier film including a substrate having a retardation value of 10 nm or less and a circularly polarizing plate (¼ wave plate+(½ wave plate)+linear polarizing plate); or a form in which a gas barrier film including a substrate having a retardation value of 100 nm to 180 nm, which can be used as a ¼ wave plate, is used in combination with a linear polarizing plate.

Examples of the substrate having a retardation value of 10 nm or less include cellulose triacetate (FUJITAC, manufactured by Fuji Corporation), polycarbonate (PUREACE, manufactured by Teijin Ltd.; ELMEC, manufactured by Kaneka Corporation), a cycloolefin polymer (ARTON, manufactured by JSR Corporation; ZEONOR, manufactured by Zeon Corporation), a cycloolefin copolymer (APEL (pellet), manufactured by Mitsubishi Chemicals Inc; TOPAS (pellet) manufactured by Polyplastics Co., Ltd.), polyarylate (U100 (pellet), manufactured by Unitika Ltd.), and transparent polyimide (NEOPULIM, manufactured by Mitsubishi Gas Chemical Co., Inc.).

In addition, as the ¼ wave plate, the above-described film can be used after being appropriately stretched to have a desired retardation value.

Since the gas barrier film according to the present invention is used for a device such as an organic EL element, it is preferable that the plastic film is transparent. That is, the light transmittance is typically 80% or higher, preferably 85% or higher, and still more preferably 90% or higher. The light transmittance can be measured using a method described in JIS K 7105. That is, using an integrating sphere light transmittance measuring device, the total light transmittance and the scattered light amount are measured, and the diffuse transmittance is subtracted from the total light transmittance to obtain the light transmittance.

Even in a case where the gas barrier film according to the present invention is used for a display, the transparency is not required when it is not arranged on the observation side. Therefore, in this case, the plastic film may be formed of an opaque material. Examples of the opaque material include polyimide, polyacrylonitrile, and a well-known liquid crystal polymer.

The thickness of the plastic film used for the gas barrier film according to the present invention is not particularly limited because it is appropriately selected according to the intended use. For example, the thickness of the plastic film is typically 1 μm to 800 μm and preferably 10 μm to 200 μm. The plastic film may have a function layer such as a transparent conductive layer or a primer layer. As the functional layer, not only the above-described layers but also layers described in paragraphs “0036” to “0038” of JP2006-289627A can be preferably used.

The barrier laminate according to the present invention can be preferably used to seal a device which may deteriorate due to water, oxygen, or the like over time when used at a normal temperature under a normal pressure. Examples of the device include an organic EL element, a liquid crystal display element, a solar cell, and a touch panel.

The barrier laminate according to the present invention can also be used as a sealing film of a device. That is, a method may be adopted in which the barrier laminate according to the present invention is provided on a surface of a device as a support. Before providing the barrier laminate, the device may be coated with a protective layer.

The barrier laminate and the gas barrier film according to the present invention can also be used as a film to seal a substrate of a device or as a film for sealing using a solid sealing method. The solid sealing method is a method in which an adhesive layer, a barrier laminate, and a gas barrier film are laminated and cured after forming a protective layer on a device. The adhesive is not particularly limited, and examples thereof include a thermosetting epoxy resin, and a photocurable acrylate resin.

(Organic EL Element)

Examples of the organic EL element in which the gas barrier film is used are described in detail in JP2007-30387A. The manufacturing process of the organic EL element includes a drying step which is performed after an etching step of ITO or a step which is performed under high-humidity conditions. Therefore, the use of the gas barrier film according to the present invention is extremely preferable.

(Solar Cell)

The barrier laminate and the gas barrier film according to the present invention can be used as a sealing film for a solar cell element. Here, it is preferable that the barrier laminate and the gas barrier film according to the present invention is sealed such that an adhesive layer is close to a solar cell element. It is required that a solar cell withstands a certain level of heat and humidity, and the barrier laminate and the gas barrier film according to the present invention is preferably applied thereto. The solar cell element in which the barrier laminate and the gas barrier film according to the present invention is preferably used is not particularly limited, and examples thereof include a single crystalline silicon solar cell element, a polycrystalline silicon solar cell element, an amorphous silicon solar cell element which is configured as a single adhesion type or a tandem structure type, a solar cell element of a Group III-V compound semiconductor such as gallium arsenide (GaAs) or indium phosphide (InP), a solar cell element of a Group II-VI compound semiconductor such as cadmium telluride (CdTe), a solar cell element of a Group compound semiconductor such as copper indium selenide (so-called CIS), copper indium gallium selenide (so-called CIGS), or copper indium gallium selenide (so-called CIGSS), a dye-sensitized solar cell element, and an organic solar cell element. Among these, in the present invention, it is preferable that the solar cell element is a solar cell element of a Group compound semiconductor such as copper indium selenide (so-called CIS), copper indium gallium selenide (so-called CIGS), or copper indium gallium selenide (so-called CIGSS).

(Others)

Other application examples include a thin film transistor described in JP1988-512104A (JP-H10-512104A), touch panels described in JP1993-127822A (JP-H5-127822A) and JP2002-48913A, and an electronic paper described in JP2000-98326A.

In addition, a laminate in which a resin film such as a polyethylene film or a polypropylene film and the barrier laminate or gas barrier film according to the present invention are laminated can be used as a sealing bag. The details can refer to, for example, the description of JP2005-247409A and JP2005-335134A.

<Optical Member>

Examples of the optical member in which the gas barrier film according to the present invention is used include a circularly polarizing plate.

(Circularly Polarizing Plate)

A λ/4 plate and a polarizing plate are laminated on the gas barrier film according to the present invention as a substrate to prepare a circularly polarizing plate. In this case, the lamination is performed such that an angle between a slow axis of the λ/4 plate and an absorption axis of the polarizing plate is 45°. It is preferable that the polarizing plate is stretched in a 45° direction with respect to a longitudinal direction (MD). For example, a polarizing plate described in JP2002-865554A can be preferably used.

### Examples

Hereinafter, the present invention will be described in detail using Examples. Materials, used amounts, ratios, treatment details, treatment procedures, and the like shown in the following Examples can be appropriately changed within a range not departing from the scope of the present invention. Accordingly, the scope of the present invention is not limited to the following specific examples.

(Evaluation 1)

### Evaluation of First Organic Layer

Polymerizable Composition for Forming Organic Layer

| | |
|---|---|
| Compound 1 | 30 parts by mass |
| Following silane coupling agent | shown in Table 1 |
| Polymerization initiator EZACURE KTO46 | 0.3 parts by mass |
| Solvent (mixed solvent containing 70 mass % of | 70 parts by mass |
| methyl ethyl ketone (MEK) and 30 mass % of | |
| propylene glycol monomethyl ether acetate (PGMEA)) | |

As titanium oxide fine particles, titanium oxide dispersion toluene (trade name: HTD-760T; high transparent titanium oxide slurry) was used. The surface of the titanium oxide dispersion toluene was coated with alumina and zirconia, in which titanium oxide nanoparticles having an average particle size of 15 nm were dispersed. The refractive index was 2.45. The titanium oxide dispersion toluene was added to the above-described polymerizable composition for forming an organic layer such that the amount of titanium oxide having a surface coated with alumina and zirconia was 30 vol % with respect to the volume of the polymerizable composition for forming an organic layer excluding the volume of the solvent. The mixture was stirred with a roller mixer and a stirrer to dissolve the components and was further dispersed with ultrasonic waves (SONIFIER). As a result, a dispersion was obtained.

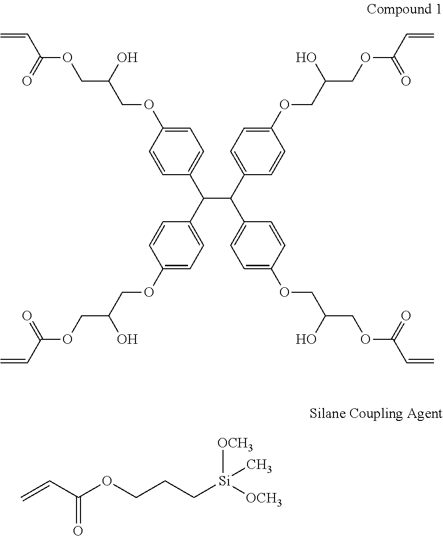

The above-described dispersion was applied to a PET substrate (manufactured by Toyobo Co., Ltd., thickness: 100 μm) using a spin coating method to form a coating film having a thickness of 2 μm, was dried at 120° C. for 4 minutes, was exposed to ultraviolet rays at about 2 J. As a result, a first organic layer was formed. Using SiH₄:H₂:NH₃ (1:5:2.4) as a source gas, a silicon nitride layer having a thickness of 50 nm was formed on a surface of the prepared first organic layer. As a result, a barrier laminate was prepared.

The results of evaluating the adhesion of the prepared barrier laminate are shown in Table 1. In the evaluation of the adhesion of the prepared barrier laminate, a 100-square tape peeling test was performed, and the number of remaining squares were counted. In the tables, the addition amount refers to a mass ratio to the total mass of Compound 1, the polymerization initiator, and the silane coupling agent.

In the first organic layer, the improvement of the adhesion was observed in a stage where the content of the silane coupling agent was 10%. However, in the silane coupling agent having no polymerizable group, the improvement of the adhesion was not observed (Examples 1 to 6 and Comparative Examples 1 to 6).

When the weight ratio of the silane coupling agent was higher than 50% during the mixing of monomers, the silane coupling agent segregated to cause cloudiness.

(Evaluation 2)

Evaluation of Second Organic Layer

The first organic layer and the inorganic layer were prepared as described above. The laminate was exposed to the air for 1 hour. Next, the above-described dispersion was applied to the above-described inorganic layer using a spin coating method to form a coating film having a thickness of 1 μm, was dried at 120° C. for 4 minutes, was exposed to ultraviolet rays at about 2 J. As a result, a second organic layer was formed. The adhesion was evaluated as described above.

In the second organic layer, the improvement of the adhesion was observed in a stage where the content of the silane coupling agent was 5%. However, in the silane coupling agent having no polymerizable group, the improvement of the adhesion was not observed (Examples 7 to 12 and Comparative Examples 7 to 12).

TABLE 1

| | | | Number of Remaining | | | |
|---|---|---|---|---|---|---|
| | | Addition | Squares in 100-Square | | | |
| Silane Coupling Agent | Place | Amount | Peeling Test | Process | n | |
| Acrylic Group Added | First Organic Layer | 0 | 0 | Standard | 1.84 | (Example 1) |
| Acrylic Group Added | First Organic Layer | 2.5 | 10 | Standard | 1.83 | Example 2 |
| Acrylic Group Added | First Organic Layer | 5 | 50 | Standard | 1.82 | Example 3 |
| Acrylic Group Added | First Organic Layer | 10 | 100 | Standard | 1.8 | Example 4 |
| Acrylic Group Added | First Organic Layer | 20 | 100 | Standard | 1.78 | Example 5 |
| Acrylic Group Added | First Organic Layer | 30 | 100 | Standard | 1.77 | Example 6 |
| Acrylic Group Added | Second Organic Layer | 0 | 0 | Standard | 1.84 | (Example 7) |
| Acrylic Group Added | Second Organic Layer | 2.5 | 20 | Standard | 1.83 | Example 8 |
| Acrylic Group Added | Second Organic Layer | 5 | 100 | Standard | 1.82 | Example 9 |
| Acrylic Group Added | Second Organic Layer | 10 | 100 | Standard | 1.8 | Example 10 |
| Acrylic Group Added | Second Organic Layer | 20 | 100 | Standard | 1.78 | Example 11 |
| Acrylic Group Added | Second Organic Layer | 30 | 100 | Standard | 1.77 | Example 12 |
| No Acrylic Group | First Organic Layer | 0 | 0 | Standard | 1.84 | Comparative |
| | | | | | | Example 1 |
| No Acrylic Group | First Organic Layer | 2.5 | 0 | Standard | 1.83 | Comparative |
| | | | | | | Example 2 |
| No Acrylic Group | First Organic Layer | 5 | 0 | Standard | 1.82 | Comparative |
| | | | | | | Example 3 |
| No Acrylic Group | First Organic Layer | 10 | 0 | Standard | 1.8 | Comparative |
| | | | | | | Example 4 |
| No Acrylic Group | First Organic Layer | 20 | 0 | Standard | 1.78 | Comparative |
| | | | | | | Example 5 |
| No Acrylic Group | First Organic Layer | 30 | 0 | Standard | 1.77 | Comparative |
| | | | | | | Example 6 |
| No Acrylic Group | Second Organic Layer | 0 | 0 | Standard | 1.84 | Comparative |
| | | | | | | Example 7 |
| No Acrylic Group | Second Organic Layer | 2.5 | 0 | Standard | 1.83 | Comparative |
| | | | | | | Example 8 |
| No Acrylic Group | Second Organic Layer | 5 | 0 | Standard | 1.82 | Comparative |
| | | | | | | Example 9 |
| No Acrylic Group | Second Organic Layer | 10 | 0 | Standard | 1.8 | Comparative |
| | | | | | | Example 10 |
| No Acrylic Group | Second Organic Layer | 20 | 0 | Standard | 1.78 | Comparative |
| | | | | | | Example 11 |
| No Acrylic Group | Second Organic Layer | 30 | 0 | Standard | 1.77 | Comparative |
| | | | | | | Example 12 |
| Acrylic Group Added | Second Organic Layer | 0 | 0 | Immediately After Formation of | 1.84 | Comparative |
| | | | | Inorganic layer | | Example 13 |
| Acrylic Group Added | Second Organic Layer | 2.5 | 0 | Immediately After Formation of | 1.83 | Comparative |
| | | | | Inorganic layer | | Example 14 |
| Acrylic Group Added | Second Organic Layer | 5 | 93 | Immediately After Formation of | 1.82 | Comparative |
| | | | | Inorganic layer | | Example 15 |
| Acrylic Group Added | Second Organic Layer | 10 | 10 | Immediately After Formation of | 1.8 | Comparative |
| | | | | Inorganic layer | | Example 16 |
| Acrylic Group Added | Second Organic Layer | 20 | 6 | Immediately After Formation of | 1.78 | Comparative |
| | | | | Inorganic layer | | Example 17 |
| Acrylic Group Added | Second Organic Layer | 30 | 30 | Immediately After Formation of | 1.77 | Comparative |
| | | | | Inorganic layer | | Example 18 |

In the evaluation of the second organic layer, the time period during which the inorganic layer was exposed to the air immediately after the formation was reduced to be within 1 minute, and the dispersion was applied using a spin coating method in a nitrogen atmosphere. Next, while changing the content of the silane coupling agent, barrier laminates were prepared, and the adhesion thereof was evaluated. (Comparative Examples 13 to 18) The adhesion decreased, and a variation increased.

(Evaluation 3)

While etching the prepared barrier laminate (Example 6) with Ar ions, the composition of the inorganic layer in the thickness direction was analyzed by ESCA.

The results are shown in FIG. 2. As shown in FIG. 2, under standard conditions, the inorganic layer was sufficiently exposed to the air after the formation. Therefore, a region of the outermost surface from 0 nm to 5 nm was oxidized.

(Evaluation 4)

A change in refractive index was measured while changing the content of titanium oxide fine particles in the second organic layer. In the polymerizable composition for forming the organic layer, the second organic layer was formed as described above by controlling the addition amount of the silane coupling agent to be 5 parts by mass.

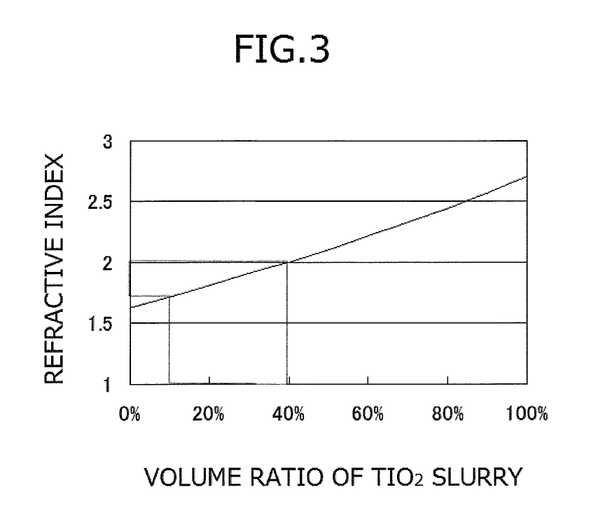

The results are shown in FIG. 3. The refractive index of Compound 1 alone was 1.58. However, as the volume ratio of the titanium oxide fine particles increased, the refractive index increased.

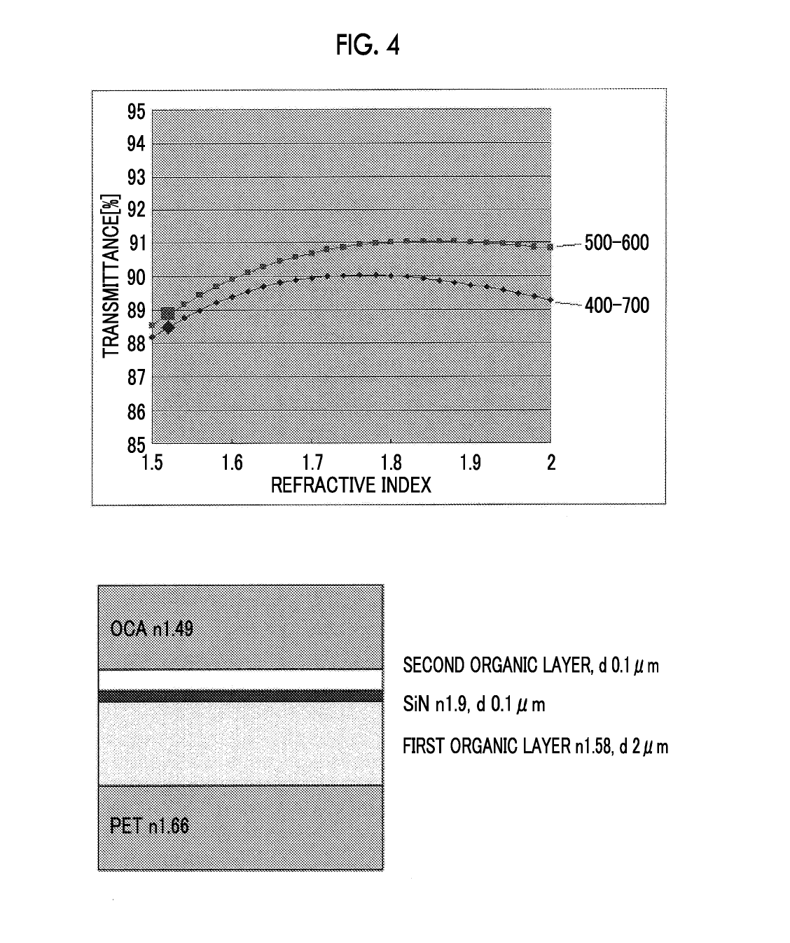

In order to verify the effect on a device, the refractive index of the second organic layer was changed in a range of 1.5 to 2 in a barrier laminate including an organic layer, an inorganic layer, and an organic layer that are formed on an optical clear adhesive (OCA) and PET, in which the refractive index of each layer was as shown in FIG. 4. The average refractive indices in a range of 400 nm to 700 nm and in a range of 500 nm to 600 nm were calculated, and the results thereof are shown in FIG. 4.

As shown in FIG. 4, with the above-described configuration, the refractive index of the organic layer was favorable at 1.7 to 1.9. This refractive index was realized when the volume ratio of titanium oxide having a surface coated with alumina and zirconia was 10% to 40%. It is known that, when the volume ratio of titanium oxide having a surface coated with alumina and zirconia is higher than 60%, cohesive peeling is likely to occur. Therefore, the volume ratio is preferably 60% or lower. In addition, from the viewpoint of securing a design margin during industrial production, the volume ratio is preferably 50% or lower.

(Evaluation 5)

An organic layer (corresponding to the organic layer in Example 6) was prepared using the same method as that of preparing the first organic layer from the polymerizable composition for forming an organic layer. An organic layer was prepared using the same method as that of preparing the organic layer in Example 6, except that titanium oxide dispersion toluene was not added to prepare the polymerizable composition for forming an organic layer. Using these organic layers, barrier properties between a case where an inorganic layer formed of Al₂O₃ was formed using a sputtering method and a case where an inorganic layer formed of SiN was formed using a CVD method. Barrier properties were measured at 40° C. and 90% using a MOCON method. The results are shown in Table. 2.

TABLE 2

| | No TiO₂ | TiO₂ Added |
|---|---|---|
| Al₂O₃ | 0.0004 | 0.1 |
| | (Detection Limit or Lower) | |
| SiN | 0.0004 | 0.0004 |
| | (Detection Limit or Lower) | (Detection Limit or Lower) |

(g/m²/day)

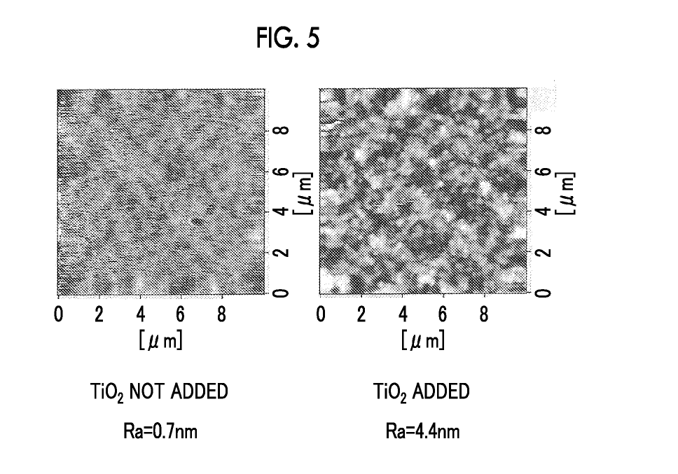

In addition, the results of measuring the atomic force microscope image (AFM) of surfaces of the two organic layers are shown in FIG. 5. It was found from FIG. 5 that the surface of the organic layer was roughened due to the addition of TiO₂. It was found from Table 2 and FIG. 5 that barrier properties which may decrease due to the rough surface of the organic layer were maintained without deterioration due to the inorganic layer formed using a CVD method.

### EXPLANATION OF REFERENCES

1: first organic layer
2: inorganic layer
3: second organic layer
4: substrate

What is claimed is:

1. A barrier laminate comprising:
an inorganic layer; and
a first organic layer,
wherein the inorganic layer and the first organic layer are in direct contact with each other,
the first organic layer is formed by curing a polymerizable composition containing a polymerizable compound, a polymerization initiator, and a silane coupling agent represented by the following Formula (1): 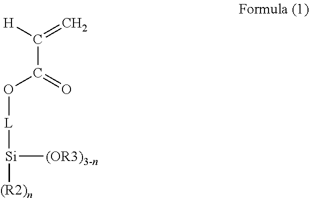
where R2 represents a halogen element or an alkyl group, R3 represents a hydrogen atom or an alkyl group, L represents a divalent linking group, and n represents an integer of 0 to 2,
the first organic layer contains titanium oxide fine particles, and
the inorganic layer is formed on a surface of the first organic layer using a chemical vapor deposition method.

2. The barrier laminate according to claim 1,
wherein a ratio of the mass of the silane coupling agent to the total mass of the polymerizable compound, the polymerization initiator, and the silane coupling agent is 2.5 mass % or higher and lower than 50 mass %.

3. The barrier laminate claim 1, further comprising:
a second organic layer,
wherein the inorganic layer and the second organic layer are in direct contact with each other,
the second organic layer is formed by curing a polymerizable composition containing a polymerizable compound, a polymerization initiator, and the silane coupling agent represented by Formula (1), and
the second organic layer contains titanium oxide fine particles.

4. The barrier laminate claim 2, further comprising:
a second organic layer,
wherein the inorganic layer and the second organic layer are in direct contact with each other,
the second organic layer is formed by curing a polymerizable composition containing a polymerizable compound, a polymerization initiator, and the silane coupling agent represented by Formula (1), and
the second organic layer contains titanium oxide fine particles.

5. The barrier laminate according to claim 3,
wherein in the first organic layer, a ratio of the mass of the silane coupling agent to the total mass of the polymerizable compound, the polymerization initiator, and the silane coupling agent is 10 mass % to 30 mass %, and
in the second organic layer, a ratio of the mass of the silane coupling agent to the total mass of the polymerizable compound, the polymerization initiator, and the silane coupling agent is 5 mass % to 30 mass %.

6. The barrier laminate according to claim 4,
wherein in the first organic layer, a ratio of the mass of the silane coupling agent to the total mass of the polymerizable compound, the polymerization initiator, and the silane coupling agent is 10 mass % to 30 mass %, and
in the second organic layer, a ratio of the mass of the silane coupling agent to the total mass of the polymerizable compound, the polymerization initiator, and the silane coupling agent is 5 mass % to 30 mass %.

7. The barrier laminate according to claim 3,
wherein the polymerizable composition used for forming the first organic layer is the same as the polymerizable composition used for forming the second organic layer.

8. The barrier laminate according to claim 4,
wherein the polymerizable composition used for forming the first organic layer is the same as the polymerizable composition used for forming the second organic layer.

9. The barrier laminate according to claim 5,
wherein the polymerizable composition used for forming the first organic layer is the same as the polymerizable composition used for forming the second organic layer.

10. The barrier laminate according to claim 6,
wherein the polymerizable composition used for forming the first organic layer is the same as the polymerizable composition used for forming the second organic layer.

11. The barrier laminate according to claim 1,
wherein the inorganic layer is formed of silicon nitride or silicon oxynitride.

12. The barrier laminate according claim 11,
wherein a thickness of the inorganic layer is 15 nm to 50 nm, and
a percentage oxygen content in a region within 5 nm from a surface of the inorganic layer opposite to the first organic layer side is higher than those of other regions of the inorganic layer.

13. The barrier laminate according to claim 1,
wherein the polymerizable composition for forming the first organic layer does not contain a silane coupling agent having no polymerizable group.

14. The barrier laminate according to claim 1,
wherein a ratio of the volume of the titanium oxide fine particles to the volume of the organic layer is 15% to 50%.

15. The barrier laminate according to claim 1,
wherein a structure is adopted in which at least two organic layers and at least two inorganic layers are alternately laminated.

16. The barrier laminate according to claim 1,
wherein the polymerizable compound is an acrylic compound.

17. The barrier laminate according to claim 1,
wherein the polymerizable compound is a polyfunctional acrylic compound having at least a bifunctional or higher polymerizable group.

18. A gas barrier film comprising:
a substrate; and
the barrier laminate according to claim 1.

19. A device comprising:
a substrate that includes the barrier laminate according to claim 1.

20. A device which is sealed using the barrier laminate according to claim 1.
